(19) United States
(12) Patent Application Publication
(10) Pub. No.: US 2019/0019903 A1
(43) Pub. Date: Jan. 17, 2019

(54) SILICON WAVEGUIDE INTEGRATED WITH SILICON-GERMANIUM (Si-Ge) AVALANCHE PHOTODIODE DETECTOR

(71) Applicants: Jinlin Ye, Eastvale, CA (US); Shirong Liao, Eastvale, CA (US)

(72) Inventors: Jinlin Ye, Eastvale, CA (US); Shirong Liao, Eastvale, CA (US)

(21) Appl. No.: 16/036,824

(22) Filed: Jul. 16, 2018

Related U.S. Application Data
(60) Provisional application No. 62/533,018, filed on Jul. 15, 2017.

(51) Int. Cl. H01L 31/0232; H01L 31/107; H01L 31/0288; H01L 31/18; H01L 31/105; G02B 6/136

(52) U.S. Cl. CPC H01L 31/02327; H01L 31/1075; H01L 31/0288; G02B 2006/12123; H01L 31/105; G02B 6/136; H01L 31/1804

(57) ABSTRACT

A method for manufacturing an integrated avalanche photodetector comprising steps of providing a silicon-insulator substrate including a top layer, an insulator layer and a base layer; partially removing the top layer to form an optical waveguide over the insulator layer; forming an opening at least through the cladding layer and the insulator layer extending to a first portion of the base layer; and forming an avalanche photodetector over the first portion of the base layer at least in the opening and optically coupled to the waveguide. In one embodiment, the avalanche photodetector is butt-coupled to the optical waveguide. In another embodiment, the avalanche photodetector is evanescently coupled to the optical waveguide.

### CROSS-REFERENCE TO RELATED APPLICATIONS

This application claims priority under 35 U.S.C. § 119 (e) to U.S. Provisional Patent Application Ser. No. 62/533,018, filed on Jul. 15, 2017, the entire contents of which are hereby incorporated by reference.

### FIELD OF THE INVENTION

The present invention relates to a Silicon-Germanium (Si—Ge)-based avalanche photodiode detector, and more particularly to a silicon waveguide integrated with Si—Ge avalanche photodiode detector.

### BACKGROUND OF THE INVENTION

Silicon photonic optical links have become a promising interconnect vehicle for data communication within data centers and high-performance computers at short distances, as well as for long-haul telecommunication, due to both low cost and complementary metal-oxide semiconductor (CMOS) compatibility.

A photodiode is very often used as means to convert an optical signal into an electric signal at high speed. A typical one is a pin-type photodiode. The pin-type photodiode is constructed in such a structure in which a i-layer of an intrinsic semiconductor is sandwiched between a p-layer of a p-type semiconductor and an p-layer of an n-type semiconductor. At the time of operation of the pin-type photodiode, a reverse bias Voltage V_{R} supplied from a bias power source is applied between the p-layer and the n-layer of the diode, so that substantially the whole region of the high resistance i-layer is converted to a layer of charge carrier depletion. An electric field exists in the depleted i-layer.

At such a case, when a photon having energy larger than the band gap Eg of the semiconductor composing the i-layer is incident and absorbed in the i-layer, electron-hole pairs are generated. The generated electrons and holes are accelerated by the electric field existing in the depleted i-layer, so that the electrons are drifted in the direction of the n-layer, and the holes are drifted in the direction of the p-layer. At that step, when the electrons and the holes encounter each other, they again form electron-hole pairs and disappear due to recombination between them. The concentrations n, and p, of the residual free carriers in the depleted i-layer are nᵢ˜0 and pᵢ˜0. Thus, it is possible to neglect that the concentrations nₚₕ, and pₚₕ, of the photo-carriers generated by the photo-absorption are reduced due to the recombination between the photo carriers and the residual free carriers. When electrons generated by the photo-absorption reach the n-layer, they are outputted as “photocurrent from the photodiode. The amount of the outputted “photocurrent corresponds to the number of photons (“absorbed photon amount”) which are absorbed in the i-layer to generate the electron-hole pairs. The amount of the outputted “photocurrent” Iₚₕ, which is converted by a load resistor R_{load} into a voltage, is detected as a signal voltage of V_{signal.}(=Iₚₕ×R_{load}).

The main factors which limit the response speed of the optic-to-electric conversion by the pin type photodiode are the time constant of the circuit, which is determined by the product (R_{load}·C) of the load resistor R_{load} and the electric capacitance C formed by the depletion layer, and the carrier travelling time, which is required for the electrons and holes to pass through the depletion layer.

On the other hand, a photodetector having sensitivity in a wavelength range from the 1.3 μm band to the 1.55 μm band is required in order to perform optical fiber communication at very high speed and over a long distance. Conventionally, a photodetector using a compound semiconductor based material, such as InGaAs, has been used. However, by the use of SiGe or Ge which have sensitivity in the wavelength range from the 1.3 μm band to the 1.55 μm band, it has become possible to realize a low cost photodetector to which a silicon process can be applied.

In a process of manufacturing a p-i-n type Ge photodiode, a Ge layer is, for example, selectively epitaxially grown on a highly doped Si layer by using SiO₂, as a mask, and then an upper electrode layer is further grown to laminate thereon, and thereby, a mesa structure is produced. Alternatively, after a heavy doped layer used as an electrode is formed on a planar Substrate, a Ge layer is epitaxially grown thereon; an upper electrode layer is further grown to laminate thereover, and then, the layers are etched to produce a mesa structure therefrom.

It is well known that an avalanche photodiode (APD) which is generated by avalanche multiplication to increase internal gain with high sensitivity and responsivity, may provide much higher responsivity due to its internal carrier multiplication mechanism and silicon is one of the best materials for APD because of its favorable ionization coefficient ratio. A normal incident Ge/Si APD with a conventional separate absorption, charge, and multiplication (SACM) structure has been demonstrated recently for 1.3-μm light detection, in which an i-Si multiplication layer, a p-Si charge layer, and an i-Ge absorbing layer were epitaxially grown on an n+-Si substrate sequentially.

The internal gain of an APD comes from the following semiconductor impact ionization property: at high enough electric field, high kinetic energy carriers bombard electronic bounds, losing their energies and creating multiple carriers. At telecom wavelengths, APDs were conventionally built on III-V materials for photon absorption, however silicon is a much better material for the APD gain multiplication region compared to most III-V materials as it has a much lower impact ionization ratio (the ratio between the impact ionization coefficients of electron and holes, and k=0.02 for bulk silicon) and consequently lower excess noises. However, there is still a need for a high performance APD with high sensitivity and wide bandwidth, and thus a butt-coupled APD has been developed.

### SUMMARY OF THE INVENTION

It is an object of the present invention to provide a silicon waveguide integrated with integrated with Si/Ge avalanche photodiode detector (APD).

It is another object of the present invention to provide a Si/Ge-based APD with high sensitivity and wide bandwidth efficiently butt-coupled with a large cross-section silicon waveguide.

In one aspect, fabrication of the integrated waveguide-based photodetector having lateral PIN configuration may include a substrate having a base semiconductor layer and an insulator layer disposed thereon. The insulator layer may serve as a bottom cladding layer of the waveguide. Furthermore, a top semiconductor layer is disposed over the insulator layer. In a particular embodiment, the substrate is an SOI (Silicon on Insulator) wafer such that the top and the base semiconductor layers consist essentially of single-crystal silicon and the insulator layer consists essentially of silicon dioxide. A waveguide is defined on the layer, for example, by masking the desired configuration of the waveguide using a patterned photoresist layer and then etching the exposed portions of the layer. In one embodiment, the APD can be fabricated on a 220 nm SOI substrate with 3 μm-thick buried oxide.

An opening is then defined on the substrate. In one embodiment, the opening can be formed by etching the top semiconductor layer. More specifically, the opening can be formed by etching the top semiconductor layer down to 0.6 μm above the insulator layer. The opening can be formed by any method known in the art, for example, by applying a patterned photoresist layer over the top semiconductor layer followed by etching of portions of the layers exposed by the photoresist.

An avalanche photodiode detector (APD) can then be formed in the opening and butt-coupled with the waveguide. More specifically, the APD formed in the opening is butt-coupled with the waveguide such that a butt end of the waveguide is part of the sidewall of the APD.

For a fabrication process of the APD, the top semiconductor layer can be a silicon layer and the opening can be patterned and implanted with phosphorus to form an n⁺ conductive layer, and two n-type metal contacts can also be formed.

A silicon dioxide layer can be deposited and pattered, and an intrinsic silicon layer can be grown on the n⁺ conductive layer as a multiplication layer for the APD and boron can be doped on the intrinsic silicon layer to form a charge layer for the APD. In one embodiment, the charge layer can be formed by ion implantation. In another embodiment, the charge layer can be formed by in situ doping during the growth of the silicon layer. A rapid thermal annealing process (e.g. 1000° C./60 second) may be followed after the charge layer is formed. A germanium layer can be grown on top of the charge layer for a predetermined thickness followed by another thermal annealing process and boron is implanted on the germanium layer to form a p-contact for the APD.

In another aspect, a method for manufacturing an integrated avalanche photodetector may include steps of providing a silicon-insulator substrate including a top layer, an insulator layer and a base layer; partially removing the top layer to form an optical waveguide over the insulator layer; forming an opening at least through the cladding layer and the insulator layer extending to a first portion of the base layer; and forming an avalanche photodetector over the first portion of the base layer at least in the opening and optically coupled to the waveguide.

### BRIEF DESCRIPTION OF THE DRAWINGS

FIG. 1 is a schematic view of the photodetector having a silicon waveguide in the present invention.

FIG. 2 is a schematic view of the photodetector defining an opening for an avalanche photodiode detector (APD) that may be butt-coupled with the silicon waveguide in the present invention.

FIG. 3 is a schematic view of the photodetector that the APD is butt-coupled with the silicon waveguide in the present invention.

FIGS. 4a-4d illustrate a process flow to fabricate the APD in the present invention.

FIG. 5 is a flow diagram of manufacturing an integrated avalanche photodetector in the present invention.

FIG. 6 is a flow diagram of forming an avalanche photodetector in the present invention.

### DETAILED DESCRIPTION OF THE INVENTION

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

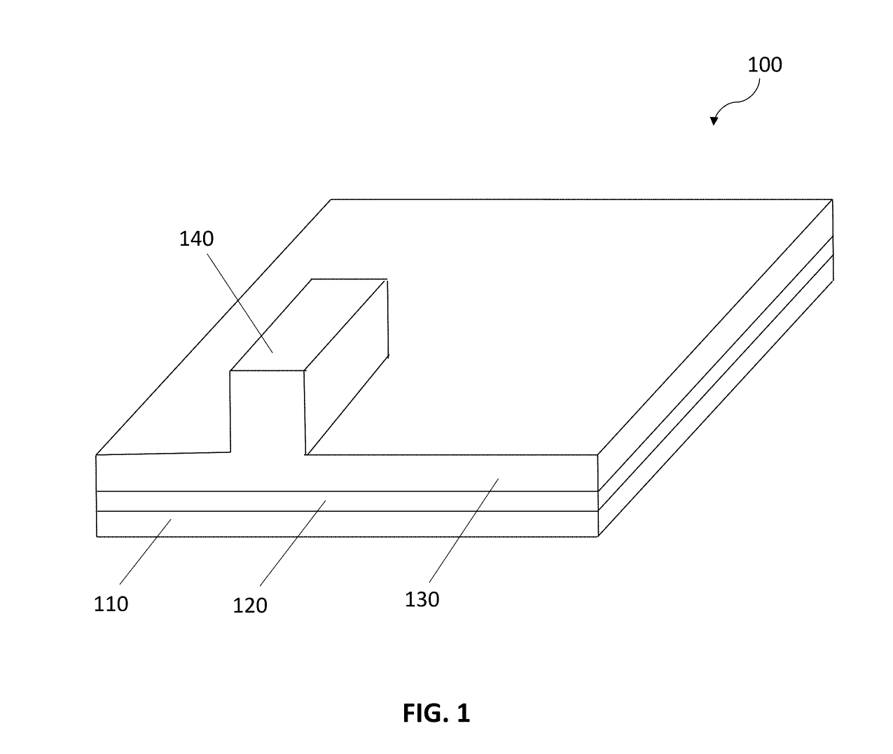

In one aspect, as shown in FIG. 1, fabrication of a silicon waveguide integrated with integrated with Si/Ge avalanche photodiode detector (APD) 100 may include a substrate having a base semiconductor layer 110 and an insulator layer 120 disposed thereon. The insulator layer 120 may serve as a bottom cladding layer of the waveguide. Furthermore, a top semiconductor layer 130 is disposed over the insulator layer 120. In a particular embodiment, the substrate is an SOI (Silicon on Insulator) wafer such that the top and the base semiconductor layers consist essentially of single-crystal silicon and the insulator layer consists essentially of silicon dioxide. A waveguide 140 is defined on the layer 130, for example, by masking the desired configuration of the waveguide using a patterned photoresist layer and then etching the exposed portions of the layer 130. In one embodiment, the APD 100 can be fabricated on a 220 nm SOI substrate with 3 μm-thick buried oxide.

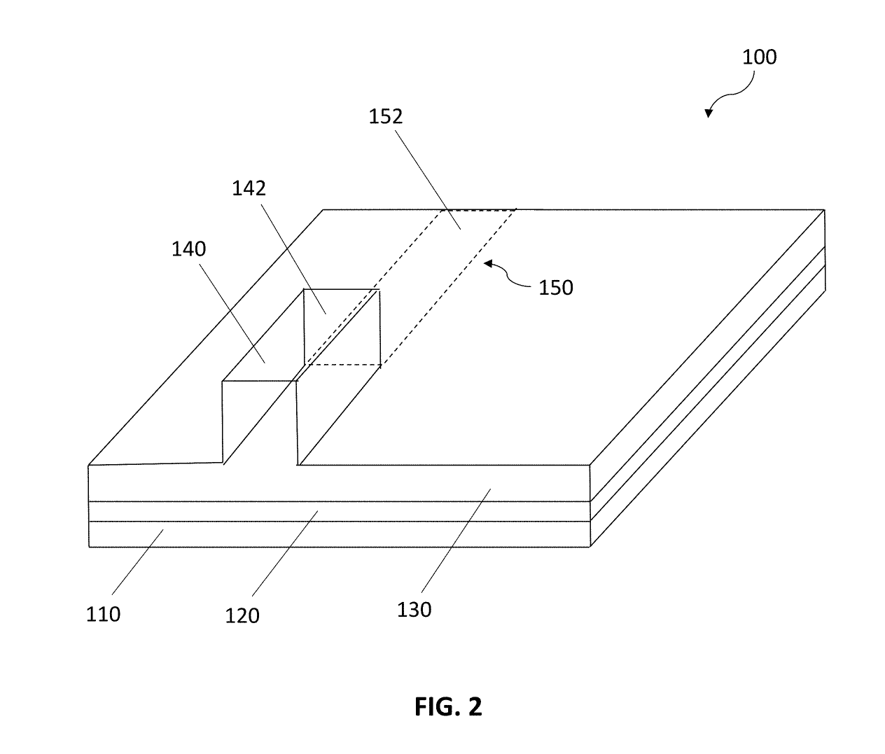

Referring to FIG. 2, an opening 150 is then defined on the substrate. In one embodiment, the opening 150 can be formed by etching the top semiconductor layer 130. More specifically, the opening 150 can be formed by etching the top semiconductor layer 130 down to 0.6 μm above the insulator layer 120. The opening 150 can be formed by any method known in the art, for example, by applying a patterned photoresist layer over the top semiconductor layer followed by etching of portions of the layers exposed by the photoresist.

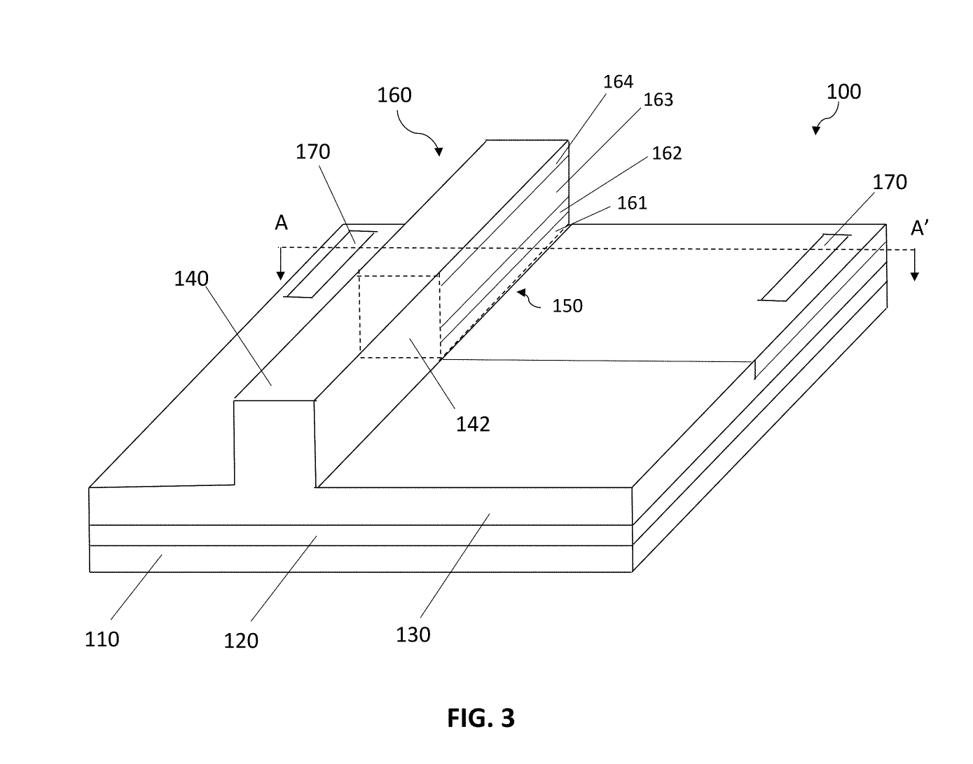

As shown in FIG. 3, an avalanche photodiode detector (APD) 160 can be formed in the opening 150 and butt-coupled with the waveguide 140. More specifically, the APD 160 formed in the opening 150 is butt-coupled with the waveguide 140 such that a butt end 142 of the waveguide 140 is part of the sidewall of the APD 160.

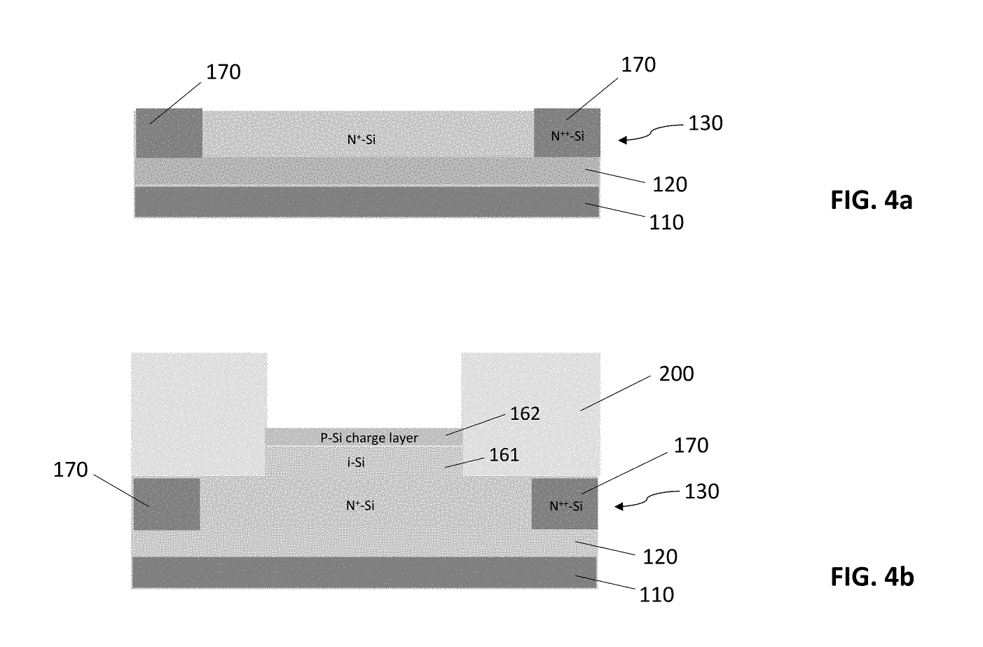

A series of cross-section views (along line A-A′ in FIG. 3) of the fabrication process flow of the APD in the present invention can be seen in FIGS. 4a to 4e. In one embodiment, the top semiconductor layer 130 is a silicon layer and the opening 150 can be patterned and implanted with phosphorus to form an n⁺ conductive layer, and two n-type metal contacts 170 can also be formed as shown in FIG. 4a.

A silicon dioxide layer 200 can be deposited and pattered as shown in FIG. 4b and an intrinsic silicon layer 161 can be grown on the n⁺ conductive layer as a multiplication layer for the APD 160 and boron can be doped on the intrinsic silicon layer 161 to form a charge layer 162 for the APD 160. In one embodiment, the charge layer 162 can be formed by ion implantation. In another embodiment, the charge layer 162 can be formed by in situ doping during the growth of the silicon layer 161. A rapid thermal annealing process (e.g. 1000° C./60 second) may be followed after the charge layer 162 is formed.

As shown in FIG. 4c, a germanium layer 163 can be grown on top of the charge layer 162 for a predetermined thickness followed by another thermal annealing process and boron is implanted in the germanium layer 163 to form a p-contact for the APD 160 as shown in FIG. 4d. It is noted that the APD 160 is butt-coupled to the optical waveguide 140. In an alternative embodiment, the APD 160 can be evanescently coupled to the optical waveguide 140. It is also noted that the APD in the present invention has high responsibility and high speed. The responsivity thereof can be as high as 3 A/w, and the 3 dB bandwidth can be 25 GHz.

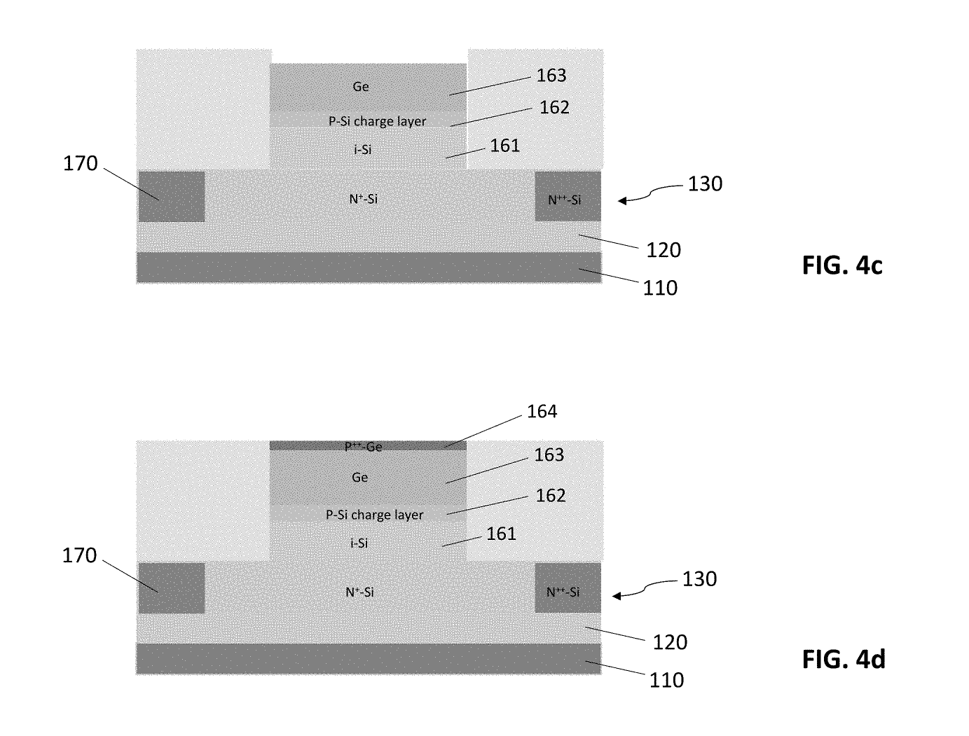

In another aspect, as shown in FIG. 5, a method for manufacturing an integrated avalanche photodetector may include steps of providing a silicon-insulator substrate including a top layer, an insulator layer and a base layer 510; partially removing the top layer to form an optical waveguide over the insulator layer 520; forming an opening at least through the cladding layer and the insulator layer extending to a first portion of the base layer 530; and forming an avalanche photodetector over the first portion of the base layer at least in the opening and optically coupled to the waveguide 540.

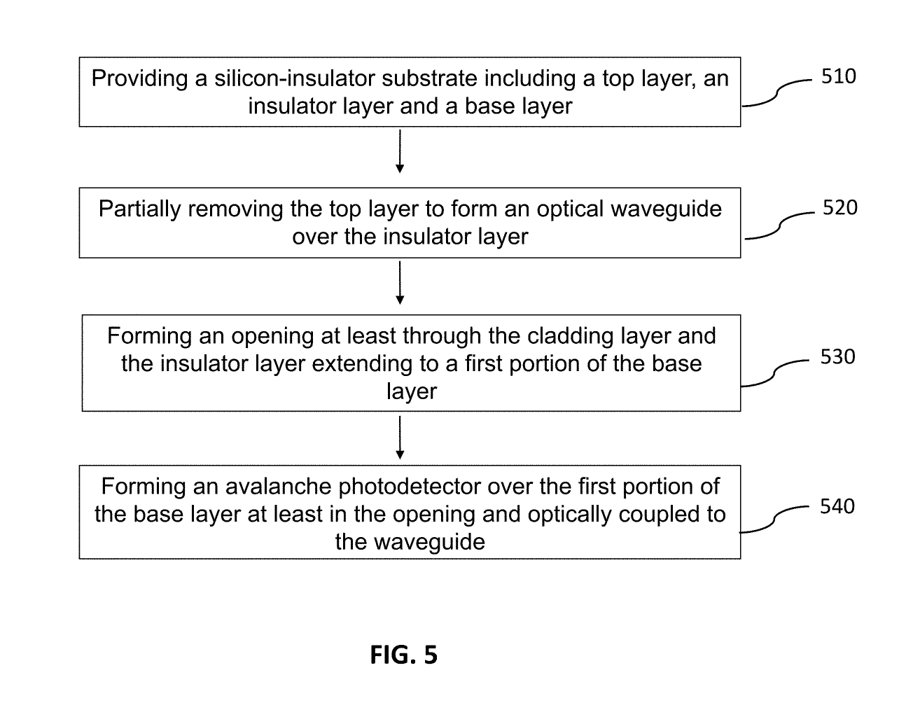

In one embodiment, the avalanche photodetector is butt-coupled to the optical waveguide. In an alternative embodiment, the avalanche photodetector is evanescently coupled to the optical waveguide. In an exemplary embodiment as shown in FIG. 6, the step of forming an avalanche photodetector 540 further includes steps of forming an n⁺ conductive layer by doping the top silicon layer with an n-type metal 541; growing an intrinsic silicon layer on top of the n⁺ conductive layer to form a multiplication layer 542; forming a charge layer on top of the multiplication layer 543; growing a germanium layer on top of the charge layer 544; and forming a p-type metal layer on top of the germanium layer 545.

While generally described in connection with germanium or silicon-germanium photodetectors integrated with silicon or silicon-based optical waveguides employing silicon or SOI wafers as starting substrates, the invention is not thusly limited and other materials and starting substrates are contemplated without departing from the scope or spirit of the invention.

Having described the invention by the description and illustrations above, it should be understood that these are exemplary of the invention and are not to be considered as limiting. Accordingly, the invention is not to be considered as limited by the foregoing description, but includes any equivalent.

What is claimed is:

1. An integrated photodetector comprising: a substrate comprising a first insulator layer disposed over a base layer, the base layer comprising a first semiconductor material, the first cladding layer defining an opening extending to the base layer; an optical waveguide comprising the first semiconductor material and disposed over the substrate; and an avalanche photodetector optically coupled to the waveguide, at least a portion of the avalanche photodetector extending above the first cladding layer and aligned with the waveguide.

2. The integrated photodetector of claim 1, wherein the avalanche photodetector is butt-coupled to the optical waveguide.

3. The integrated photodetector of claim 1, wherein the avalanche photodetector is evanescently coupled to the optical waveguide.

4. The integrated photodetector of claim 1, wherein the avalanche photodetector includes a silicon layer doped with an n-type metal to form an n⁺ conductive layer; an intrinsic silicon layer grown on top of the n⁺ conductive layer to form a multiplication layer; a charge layer formed on top of the multiplication layer; a germanium layer grown on the charge layer and a p-type metal layer formed on top of the germanium layer.

5. The integrated photodetector of claim 4, wherein the charge layer is formed by doping boron in the intrinsic silicon layer.

6. The integrated photodetector of claim 4, wherein the n-type metal is phosphorus.

7. The integrated photodetector of claim 4, wherein the p-type metal layer is formed by doping boron in the germanium layer.

8. A method for manufacturing an integrated avalanche photodetector comprising steps of providing a silicon-insulator substrate including a top layer, an insulator layer and a base layer; partially removing the top layer to form an optical waveguide over the insulator layer; forming an opening at least through the cladding layer and the insulator layer extending to a first portion of the base layer; and forming an avalanche photodetector over the first portion of the base layer at least in the opening and optically coupled to the waveguide.

9. The method for manufacturing an integrated photodetector of claim 8, wherein the avalanche photodetector is butt-coupled to the optical waveguide.

10. The method for manufacturing an integrated photodetector of claim 8, wherein the avalanche photodetector is evanescently coupled to the optical waveguide.

11. The method for manufacturing an integrated photodetector of claim 8, wherein the step of forming an avalanche photodetector further includes steps of forming an n⁺ conductive layer by doping the top silicon layer with an n-type metal; growing an intrinsic silicon layer on top of the n⁺ conductive layer to form a multiplication layer; forming a charge layer on top of the multiplication layer; growing a germanium layer on top of the charge layer; and forming a p-type metal layer on top of the germanium layer.

12. The method for manufacturing an integrated photodetector of claim 11, wherein the charge layer is formed by doping boron in the intrinsic silicon layer.

13. The method for manufacturing an integrated photodetector of claim 11, wherein the n-type metal is phosphorus.

14. The method for manufacturing an integrated photodetector of claim 11, wherein the p-type metal layer is formed by doping boron in the germanium layer.
